(19) United States
(12) Patent Application Publication
(10) Pub. No.: US 2003/0114008 A1
(43) Pub. Date: Jun. 19, 2003

(54) Method for forming metal wire of semiconductor device

(76) Inventors: Hyun-jin Jang, Icheon-shi (KR); Jong-yoon Yoon, Seoul-shi (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/321,755

(22) Filed: Dec. 17, 2002

(30) Foreign Application Priority Data
Dec. 19, 2001 (KR) 2001-81381

(51) Int. Cl. H01L 21/311

(52) U.S. Cl. 438/694

(57) ABSTRACT

A method for forming a metal wire of a semiconductor device is disclosed. The method for forming a metal wire of a semiconductor device can reduce a junction leakage current and improve the reliability of a semiconductor device by forming a silicon thin film on a silicon substrate with a contact hole before depositing a titanium film or a titanium nitride film in order to improve contact resistance caused by the increase of a dopant concentration by maximally suppressing the formation of a titanium silicide film on a junction area in the silicon substrate in the heat treatment process.

### BACKGROUND

1. Technical Field

Methods for forming metal wires of semiconductor devices are disclosed and, more particularly, methods for forming metal wires of semiconductor devices which can reduce junction leakage current and improve the reliability of the semiconductor devices by forming a silicon thin film on a silicon substrate with a contact hole before depositing a titanium film or a titanium nitride film in order to improve contact resistance caused by the increase of the dopant concentration, and by maximizing the suppression of the formation of a titanium silicide film on a junction area in the silicon substrate in the heat treatment process.

2. Description of the Related Art

Generally, as the integration of a semiconductor device increases, the depth of a junction area and the size of a contact hole decrease. Therefore, it becomes difficult to adequately fill the contact hole in a process of a metal contact. Thus the contact resistance is increased and the electrical properties of the device are deteriorated.

To solve this problem, a barrier metal layer having titanium silicide (TiSi₂) is formed on the base of a contact hole by depositing titanium (Ti) and titanium nitride (TiN) and performing heat treatment thereon. In addition, with a highly integrated semiconductor device, the formation of a metal wire having a low resistance is required. As materials of the metal wire, tungsten (W), aluminum (Al), titanium (Ti), cobalt (Co), zinc (Zn), copper (Cu), silicon (Si), platinum (Pt), aurum (Au) and the like are used. Among them, to reduce the fabrication cost, tungsten and aluminum are mainly used which have a relatively low resistivity and which are easily deposited.

However, the more the device is integrated, the smaller the concentration of ions existing in the junction area. Thus the resistance of the metal wire increases gradually. Also, the contact area is reduced by the reduction of contact sizes. This generates an additional problem of increased contact resistance.

FIG. 1 is a cross-sectional view showing a method for forming a metal wire of a semiconductor device according to the conventional art.

Firstly, as illustrated in FIG. 1, an interlayer insulating film 120 is formed on a semiconductor substrate 100 in which a junction area 110 is formed. A contact hole is formed by etching a selected portion of the interlayer insulating film 120 to expose the junction area 110. Next, for electrical insulation with peripheral devices, a spacer insulating film 130 is formed on a side wall of the contact hole.

Continuously, a metal barrier layer 170 is formed by sequentially forming a titanium film 150 and a titanium nitride film 160 on top of the interlayer insulating film 120 including the contact hole by the sputtering method. Thereafter, a titanium silicide film 180 is formed on the base of the contact hole by carrying out the rapid thermal process (RTP) at an atmosphere of nitrogen (N₂) or ammonium (NH₃) gas. This titanium silicide film 180 is formed by the interaction between silicon atoms (Si) of the semiconductor substrate 100 and titanium atoms (Ti) of the titanium film 150 during the rapid thermal process.

Next, a metal layer 190 is deposited on the entire structure including the metal barrier layer 170 by the chemical vapor deposition (CVD). Then, a metal wire (not shown) is formed by pattering this metal layer 190.

However, in the conventional method for forming the metal wire, the titanium silicide film is formed on the interface between the titanium film 150 of the metal barrier layer and the silicon semiconductor substrate 100. Accordingly, B⁺ ions are diffused into the metal layer and B⁺ dopant in the metal-silicon interface is reduced, thereby increasing the resistance.

### SUMMARY OF THE DISCLOSURE

Therefore, methods for forming metal wires of semiconductor devices are disclosed which can reduce junction leakage current and improve the reliability of a semiconductor device by forming a silicon thin film on a silicon substrate with a contact hole before depositing a titanium film or a titanium nitride film in order to improve contact resistance caused by the increase of dopant concentration by suppressing the formation of a titanium silicide film on a junction area in the silicon substrate in the heat treatment process.

One disclosed method comprises forming an interlayer insulating film on a silicon substrate with a junction area, forming a contact hole by performing an etching process and then forming a spacer insulating film on a side wall of the contact hole; sequentially forming a silicon thin film and a metal barrier layer on the entire surfaces of the resultant material and then forming a titanium silicide film by performing a heat treatment process; and forming a metal layer on the metal barrier layer by a chemical vapor deposition and then forming a metal wire by patterning the metal layer.

### BRIEF DESCRIPTION OF THE DRAWINGS

The above features and advantages of the disclosed methods will become more apparent from the following detailed description when taken in conjunction with the accompanying drawings, wherein:

FIG. 1 is a cross-sectional view showing a method for forming a metal wire of a semiconductor device according to the conventional art;

FIGS. 2a to 2c are cross-sectional views showing a first disclosed method for forming a metal wire of a semiconductor device; and

FIGS. 3a to 3e are cross-sectional views showing a second disclosed method for forming a metal wire of a semiconductor device.

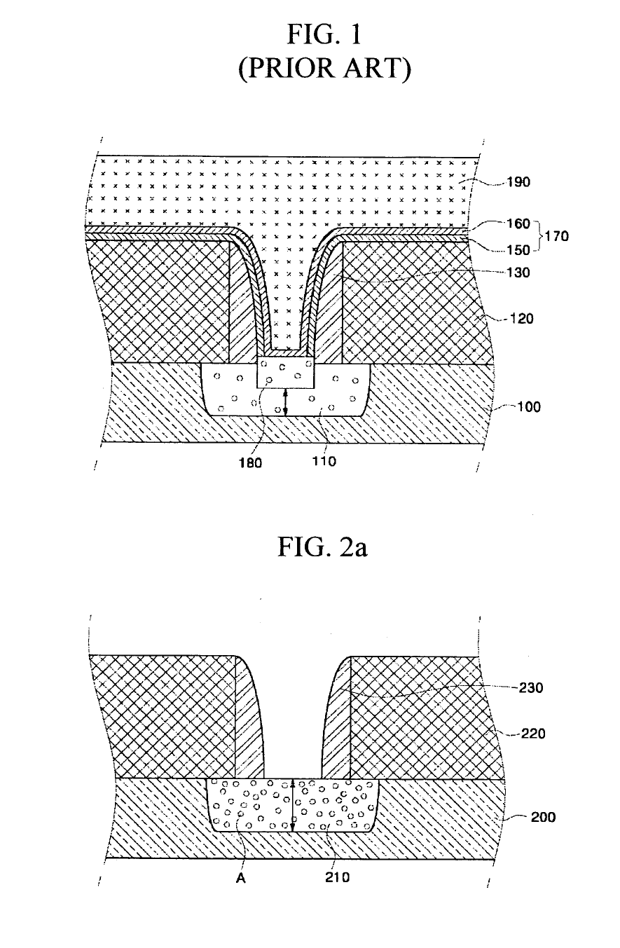

### DETAILED DESCRIPTION OF THE PRESENTLY PREFERRED EMBODIMENTS

Preferred embodiments of the disclosed methods will now be described with reference to the accompanying drawings. The preferred embodiments are intended to illustrate the principles of the disclosed methods, but not to limit the scope of this disclosure. In the following description, same drawing reference numerals are used for the same elements as those of the conventional art.

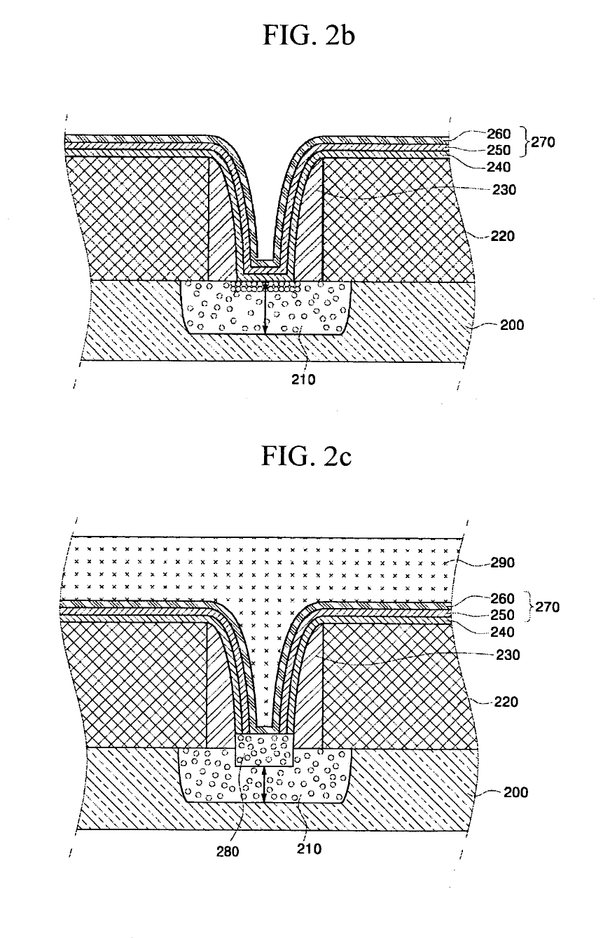

FIGS. 2a to 2c are cross-sectional views showing a first disclosed method for forming a metal wire of a semiconductor device.

Firstly, as shown in FIG. 2a, an interlayer insulating film 220 is formed on a silicon substrate 200 in which a junction area 210 is formed. A contact hole is formed by etching a selected portion of the interlayer insulating film 220 to expose the junction area 210. Next, for electrical insulation with peripheral devices, a spacer insulating film 230 is formed on a side wall of the contact hole.

Next, as shown in FIG. 2b, a silicon thin film 240 is formed by depositing pure silicon or a silicon compound on the entire surfaces of the resultant material at a thickness ranging from about 100 to about 500 Å. Then, a metal barrier layer 270 is formed by sequentially stacking a titanium film 250 and a titanium nitride film 260 by in-situ sputtering.

At this time, the silicon thin film 240 and the metal barrier layer 270 are formed in an in-situ fashion.

Then, as shown in FIG. 2c, a titanium silicide film 280 is formed by performing a heat treatment process by a rapid thermal process (RTP) or a furnace annealing at an atmosphere of nitrogen (N₂) or ammonium (NH₃) gas.

At this time, the titanium silicide film 280 is formed by a heat treatment reaction between the silicon thin film 240 and the titanium film 250 formed on an upper portion of the silicon substrate 200. Also, the titanium silicide film 280 serves to maximally avoid the diffusion of B⁺ ions (A) on the junction area in the silicon substrate 200 by suppressing the reaction between silicon ions and titanium ions on the interface of the junction area in the silicon substrate 200, as well as to prevent junction loss, thereby maximally suppressing the reduction of the concentration of dopant existing in the junction area.

Next, a metal layer 290 is formed on the titanium nitride film 260 of the metal barrier layer 270 using a metal material, tungsten, by a chemical vapor deposition. Then, a metal wire (not shown) is formed by patterning the metal layer 290.

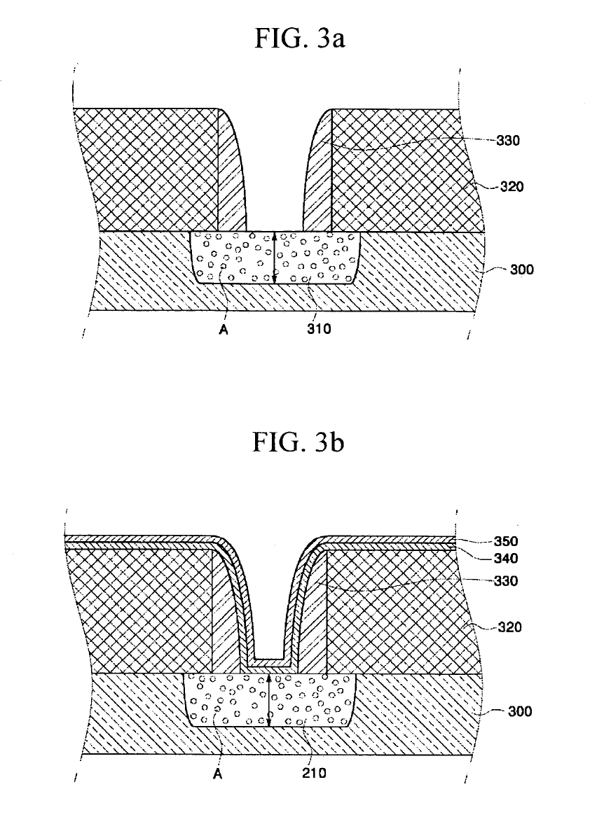

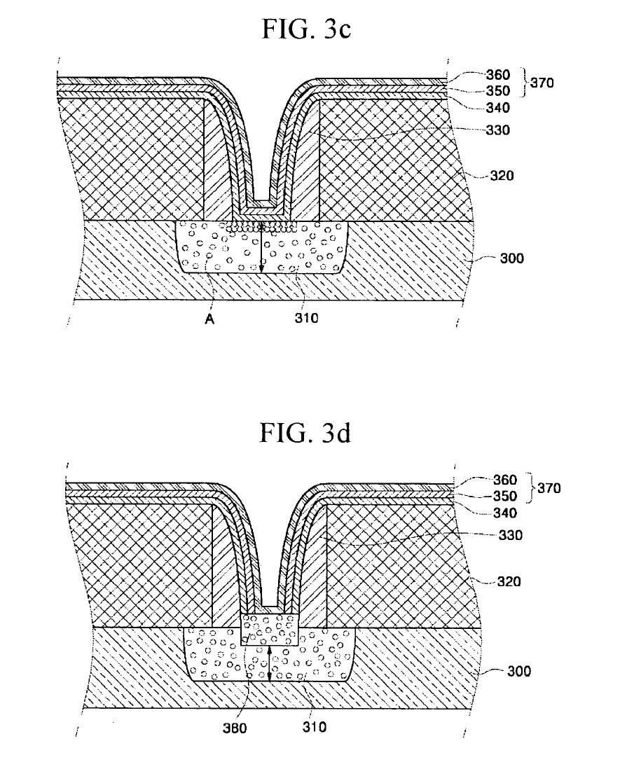

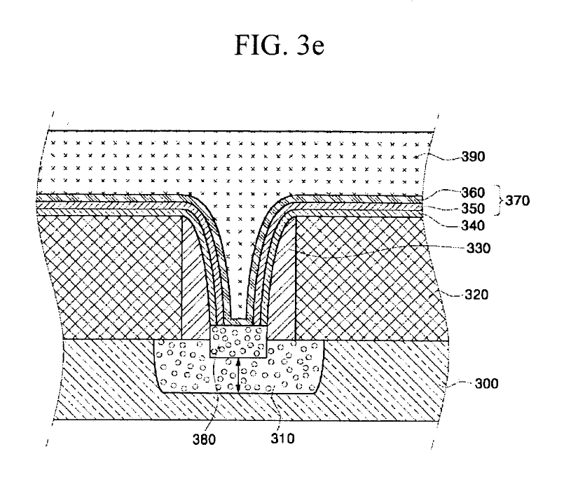

FIGS. 3a to 3e are cross-sectional views showing a second disclosed method for forming a metal wire of a semiconductor device.

Firstly, as shown in FIG. 3a, an interlayer insulating film 320 is formed on a silicon substrate 300 in which a junction area 310 is formed. A contact hole is formed by etching a selected portion of the interlayer insulating film 320 to expose the junction area 310. Next, for electrical insulation with peripheral devices, a spacer insulating film 330 is formed on a side wall of the contact hole.

Subsequently, as shown in FIG. 3b, a silicon thin film 340 is formed on the entire surfaces of the resultant material at a thickness ranging from about 100 to about 500 Å. Then, a titanium film 350, which is a lower metal barrier layer, is deposited thereon by in-situ sputtering.

Next, as shown in FIG. 3c, the resultant material is exposed to air. Then, a metal barrier layer 370 is formed by depositing a titanium nitride film 360, which is an upper metal barrier layer, by ex-situ sputtering.

Then, as shown in FIG. 3d, a heat treatment process is performed by a rapid thermal process (RTP) or a furnace annealing at an atmosphere of nitrogen (N₂) or ammonium (NH₃) gas.

At this time, a titanium silicide film 380 is formed by the reaction between the silicon thin film 340 and the titanium film 350 during the heat treatment. Also, the titanium silicide film serves to maximally avoid the diffusion of B⁺ ions (A) on the junction area in the silicon substrate 300 by suppressing the reaction between silicon ions and titanium ions on the interface of the junction area in the silicon substrate 300, as well as to prevent junction loss, thereby maximally suppressing the reduction of the concentration of dopant existing in the junction area.

Subsequently, as shown in FIG. 3e, a tungsten layer 390 is formed as a metal layer on the titanium nitride film 360, which is the upper metal barrier layer 370, by the chemical vapor deposition. Then, a metal wire (not shown) is formed by patterning the tungsten layer 390.

The disclosed methodology can reduce a junction leakage current and improve the reliability of a semiconductor device by forming a silicon thin film on a silicon substrate with a contact hole before depositing a titanium film or a titanium nitride film in order to improve contact resistance caused by the increase of a dopant concentration by suppressing the formation of a titanium silicide film on a junction area in the silicon substrate in the heat treatment process.

What is claimed is:

1. A method for forming a metal wire of a semiconductor device, the method comprising:
forming an interlayer insulating film on a silicon substrate with a junction area, forming a contact hole through the interlayer insulating film to expose a portion of the junction area, the contact hole having a side wall by performing an etching process on the interlayer insulating film and then forming a spacer insulating film on the side wall of the contact hole;
sequentially forming a silicon thin film and a metal barrier layer on the spacer insulating film and the exposed portion of the junction area and then forming a titanium silicide film on the exposed portion of the junction area from portions of the silicon thin film and metal barrier layer covering the exposed portion of the junction area by performing a heat treatment process; and
forming a metal layer on the metal barrier layer by a chemical vapor deposition and then forming a metal wire by patterning the metal layer.

2. The method of claim 1, wherein the heat treatment process is performed by a rapid thermal process.

3. The method of claim 1, wherein the heat treatment process is performed by a furnace annealing.

4. The method of claim 1, wherein the silicon thin film is formed at a thickness ranging from about 100 to about 500 Å using pure silicon.

5. The method of claim 1, wherein the silicon thin film is formed at a thickness ranging from about 100 to about 500 Å using a silicon compound.

6. The method of claim 1, wherein the metal barrier layer is formed by sequentially stacking a titanium film and a titanium nitride film.

7. The method of claim 1, wherein the silicon thin film and the metal barrier layer are deposited in an in-situ fashion.

8. The method of claim 1, wherein the silicon thin film and the titanium film of the metal barrier layer are deposited in an in-situ fashion and the titanium nitride film of the metal barrier layer is deposited in an ex-situ fashion.

9. The method of claim 1, wherein the titanium silicide film is formed by performing the heat treatment process at an atmosphere of nitrogen (N₂) gas.

10. The method of claim 1, wherein the titanium silicide film is formed by performing the heat treatment process at an atmosphere of ammonium (NH₃) gas.
